(19) United States
(12) Patent Application Publication
(10) Pub. No.: US 2010/0124023 A1
(43) Pub. Date: May 20, 2010

(54) METHOD FOR PLATING FILM ON A HEAT DISSIPATION MODULE

(76) Inventor: YU-HSUEH LIN, TAIPEI CITY (TW)

Correspondence Address: ROSENBERG, KLEIN & LEE, 3458 ELLICOTT CENTER DRIVE-SUITE 101, ELLICOTT CITY, MD, 21043, US

(21) Appl. No.: 12/352,748

(22) Filed: Jan. 13, 2009

(30) Foreign Application Priority Data
Nov. 20, 2008 (TW) 097144838

(51) Int. Cl. H05K 7/20; H05H 1/24

(52) U.S. Cl. 361/705; 427/577

(57) ABSTRACT

A method for plating film on a heat dissipation module includes the steps of: cleaning the heat dissipation module; injecting hydrogen and tetra-methylsilane gases and applying an electric current to generate a bias electric field within a working chamber, thereby plating an adherent film on the heat dissipation module; injecting hydrocarbon gas together with the hydrogen and tetra-methylisilane gases into the working chamber, thereby plating a mixed film on the adherent film; and injecting the hydrogen and tetra-methylisilane gases together with hydrocarbon gas into the working chamber, thereby plating a noncrystalline DLC film on the mixed film.

This application claims the benefit of the Taiwan Patent Application Serial NO. 097144838, filed on Nov. 20, 2008, the subject matter of which is incorporated herein by reference.

### BACKGROUND OF THE INVENTION

1. Field of the Invention

The present invention relates to a fabrication technology for a heat dissipation module, more particularly to a method for plating films on an external surface of the heat dissipation module and a film-plated heat dissipation module.

2. Description of the Prior Art

In our daily life, several of the electronic devices include a plurality of electronic elements, such as LED (light emitting diode) or a CPU (central processing unit). Operation of these electronic elements generally results in heat. Under certain condition, the heat generated thereby may affect the proper function of the electronic device, like reduction in the carrying load, shortening the service life, lowering the operation speed and effect thereof.

In order to dissipate the heat, a heat dissipation module is mounted intentionally adjacent to the heat-generating source in the electronic device. Two facts, namely the structure and the material, are taken for consideration in the presently available heat dissipation module. As far as the material is concern, conductive material is preferred for enhancing the heat dissipating effect. For the structure, the external surface area of the heat dissipation is increased as much as possible for heat exchanging operation. A conventional heat dissipation module generally includes a dissipating base and a plurality of fins extending from the dissipating base, thereby increasing the total surface area for enhancing the heat exchanging operation.

In addition, in order to enhance the heat dissipating effect, the external surfaces of the base or the fins are generally heat-treated so that the external surfaces are formed with recesses, protrusions, wrinkled portions or densely located grain-like projections. Regarding the aforesaid comments, a known structure and method is given in the following paragraphs for fabricating a heat dissipation module.

FIG. 1 shows a conventional heat dissipation module 1 to include a dissipating base 11 and a plurality of dissipating fins 12. The base 11 has a main layer 111 and an external layer 112, wherein the main layer 111 has a mounting surface 111a for disposing on a support ground and a dissipating surface 111b for dissipating the heat therefrom. The external layer 112 is disposed on and thus encloses the dissipating surface 111b of the main layer 111 from above. Each fin 12 has a base layer 121 integrally formed with the main layer 111 of the base 11, and an external layer 122 enclosing the base layer 121 from above. A function element 2 is disposed below the mounting surface 111a of the main layer 111 and generates heat upon operation. A portion of the generated heat is transferred from the main layer 111, 121 to the external layer 112, 122 and finally into the ambient air via the natural convection.

In real practice, the aforesaid external layers 112, 122 are respectively plated on the main layers 111, 112 by means of sand blasting process, extrusion machine, cutting device and impact force such that the external layers 112, 122 are formed with recesses, protrusions, wrinkled portions or densely located grain-like projections, thereby increasing a total surface area for dissipating heat effectively.

For those persons skilled in the art, it is obvious that once the external surface of the dissipation module is heat-treated, the heat dissipating effect is indeed increased but the heat treatment simultaneously ruptures the planar surface of the dissipating base 11 and the dissipating fins 12. From a microcosmic view, rupture in the external surface of the dissipating base 11 and the dissipating fins 12 causes irregular dislocation of the ions, narrowing the location space among the ions and difficulties in the machining of the external surface, which, in turn, causes reduction in the heat dissipating ability of the aforesaid external layers 112, 122.

Due to aforesaid facts, it is urgently needed to invent a new method for plating film on the external surface of a heat dissipation module in order to overcome the problems encountered during use of the prior art plating method for heat dissipation module.

### SUMMARY OF THE INVENTION

The object of the present invention is to provide a plating method for a heat dissipation module, in which, the exterior of the heat dissipation module is plated successively by an adherent film, a mixed film and a noncrystalline DLC film. The noncrystalline DLC film thus formed has regular ions location and provides enhanced heat dissipating ability.

A method for plating film on the external surface of a heat dissipation module is provided according to the present invention. The method accordingly includes the steps of: (a) preparing the heat dissipation module; (b) cleaning the external surface of the heat dissipation module; (c) disposing the heat dissipation module into a working chamber, injecting hydrogen and tetra-methylsilane [TMS; Si(CH₃)₄] gases therein and applying an electric current to generate a bias electric field within the working chamber, thereby plating an adherent film on the external surface of the heat dissipation module; (d) plating a mixed film on an external surface of the adherent film; and (e) plating a noncrystalline DLC film on the mixed film. The mixed film has a distal portion that is spaced farthermost from the heat dissipation module and that consists of larger noncrystalline DLC (diamond-like carbon) material when compared to the remaining portion of the mixed film.

When compare to the prior art method, according to the method of the present invention, the adherent film, the mixed film and the noncrystalline DLC film are successively plated on the heat dissipation module so that the noncrystalline DLC film is tightly adhered on the dissipating base and the dissipating fins. Since the noncrystalline DLC film has a balanced ions bonding and enhanced heat dissipating ability, the heat dissipating effect of the heat dissipation module is increased.

### BRIEF DESCRIPTION OF THE DRAWINGS

Other features and advantages of this invention will become more apparent in the following detailed description of the preferred embodiment of this invention, with reference to the accompanying drawings, in which:

FIG. 1 shows a conventional heat dissipation module dissipating heat generated by a function element;

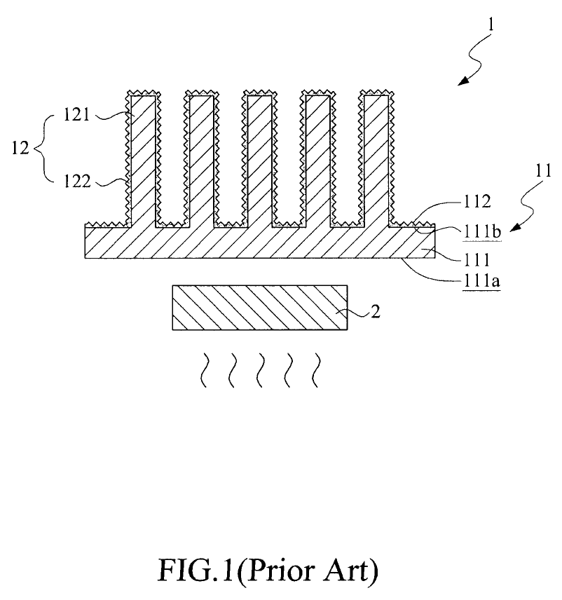

FIG. 2 illustrates a plasma enhanced chemical vapor deposition apparatus for plating films onto a heat dissipation module according to the method of the present invention;

FIG. 3 illustrates how the heat dissipation module is mounted in a working chamber for conducting the method of the present invention;

FIG. 4 illustrates gas being injected into an electric field within the working chamber during carrying out the method of the present invention;

FIG. 5 shows an adherent film being plated on a dissipating base and fins of the heat dissipation module according to the method of the present invention;

FIG. 6 is a cross sectional view of the heat dissipating module taken along an encircle portion X in FIG. 5;

FIG. 7 illustrates a mixed film being plated on the adherent film of the heat dissipation module according to the method of the present invention;

FIG. 8 is a cross sectional view of the heat dissipating module taken along an encircle portion Y in FIG. 8;

FIG. 9 illustrates a mixed film being plated on the adherent film of the heat dissipation module according to the method of the present invention;

FIG. 10 is a cross sectional view of the heat dissipating module taken along an encircle portion Z in FIG. 9; and

FIG. 11 shows a plated heat dissipation module formed according to the present method dissipating heat generated by a function element.

### DETAILED DESCRIPTION OF THE PREFERRED EMBODIMENT

The method of the present invention is used for plating film on the external surface of a heat dissipation module, thereby forming a plated heat dissipation module with effective heat dissipating properties. An example is given in the following paragraphs, but the restriction should not be limited thereto.

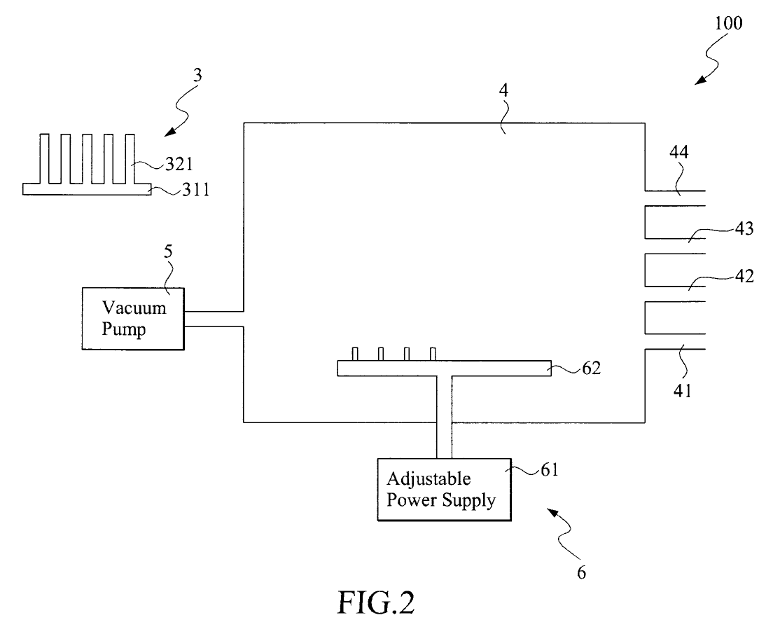

FIG. 2 illustrates a plasma enhanced chemical vapor deposition apparatus 100 for plating films on the heat dissipation module 3 according to the method of the present invention. As illustrated, the heat dissipation module 3 accordingly includes a dissipating base 311 and a plurality of fins 321 extending from or integrally formed with the dissipating base 311, which are intended for undergoing the film-plating method of the present invention, thereby forming the plated heat dissipation module. The apparatus 100 includes a working chamber 4, a vacuum pump 5 for pumping out air from the chamber 4, a power control device 6. The chamber 4 is formed with four vents 41,42,43,44. The power control device 6 includes an adjustable power supply 61 disposed exterior of the chamber 4, a conductive carrier frame 62 extending into the chamber 4 from the power supply 61.

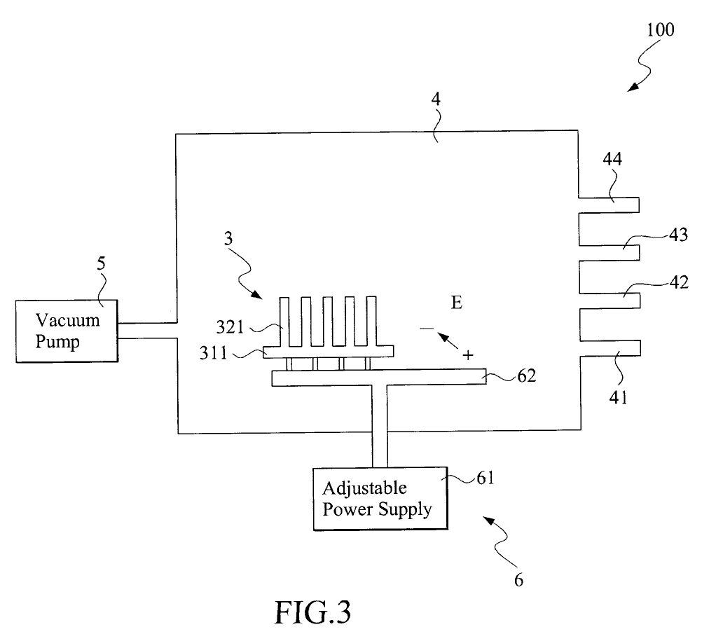

FIGS. 3 to 10 illustrates one embodiment of the film-plating method of the present invention. Firstly, the heat dissipation module 3 is erected securely on the carrier frame 62 as shown in FIG. 3 and is connected electrically to the power supply 61. An electric current is applied so as to generate a bias electric field within the chamber 4.

The pump 5 is activated to pump out the air from the working chamber 4, thereby converting into a vacuum chamber. The power supply 61 supplies an external electric current to the carrier frame 62 so that a high current level is existed in the frame 62 while a lower current level is existed in the chamber, thereby forming the bias electric field E.

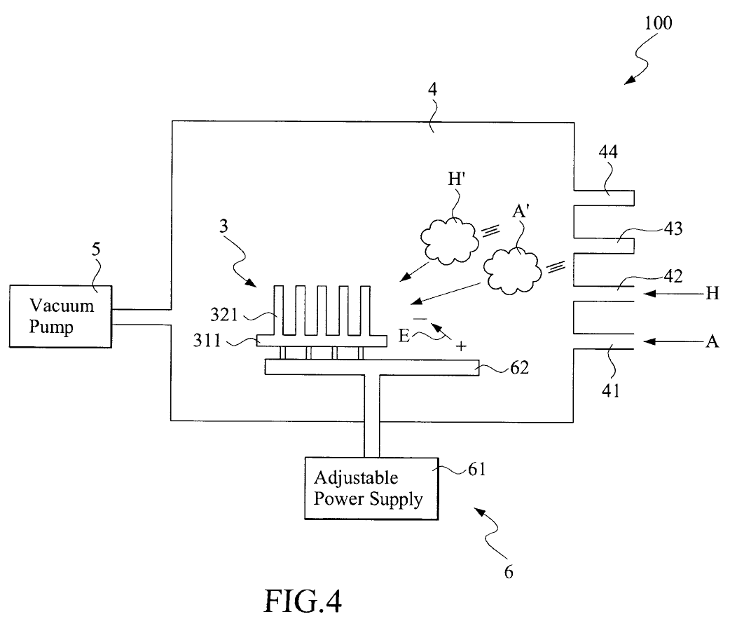

Referring to FIG. 4, gases are injected into the bias electric field in the vacuum chamber, where the gases become plasma-like ions after ionization process. In this embodiment, when plating a film on the heat dissipation module 3, H (hydrogen) and A (argon) gases are injected into the chamber 4 via the vents 41, 42 after shutting the vents 43, 44, wherein the gases convert into hydrogen ions H′ and argon ions A′ due to the bias electric field E. The hydrogen and argon ions thus formed will collide against the heat dissipation module 3, thereby cleaning the external surface thereof.

The cleaning operation of the heat dissipation module 3 includes a first cleaning section of 10-35 minutes and a second cleaning section of 10-45 minutes. During the first cleaning section, the pressure in the vacuum chamber is maintained under 2-4 μbar, the bias electric field E at 300-700V (Voltage) and the power of the applied electric current at 600-1400 W (watt), respectively. At the same, the flow rate of argon and hydrogen is maintained at 50-200 sccm (standard cc/min) respectively.

During the second cleaning time, the pressure in the working chamber is maintained under of 2-15 μbar, the bias electric field E at 300-700V and the power of the applied electric current at 600-1400 W. During this time, the flow rate of H is at 50-200 sccm while the flow rate of A is at 200-400 sccm (standard cc/min).

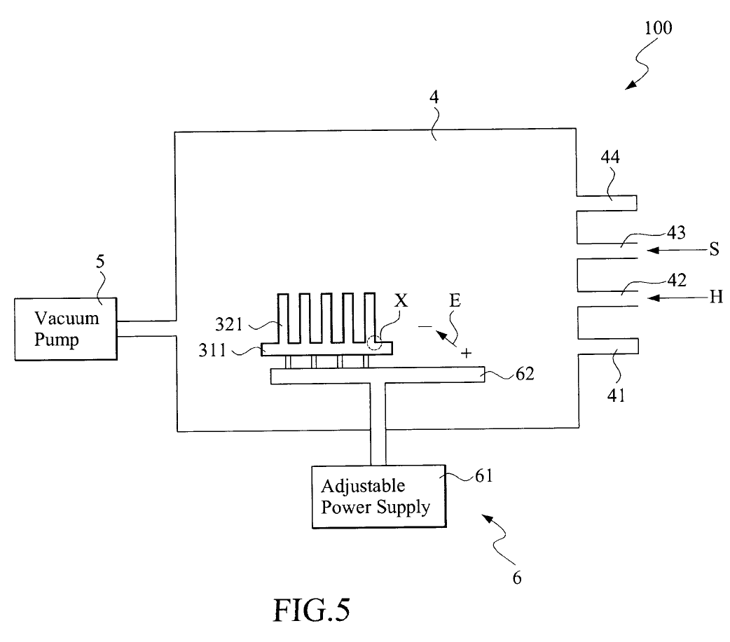

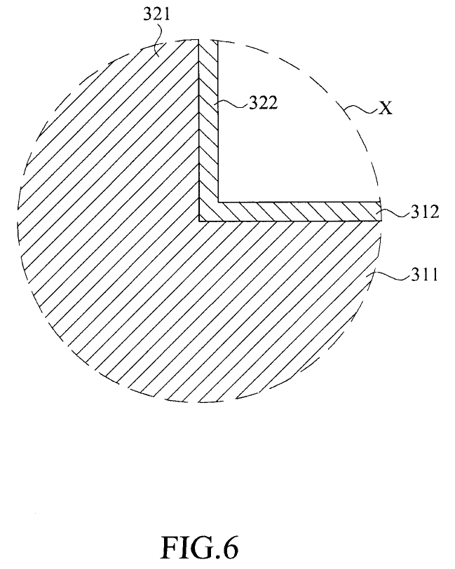

FIG. 5 shows an adherent film 322 being plated on the dissipating base 311 and the dissipating fins 321 of the heat dissipation module 3 according to the method of the present invention. FIG. 6 is an enlarged view of the encircled portion (X) shown in FIG. 5. For plating the adherent film 322, the vents 41 and 44 are closed firstly and hydrogen and tetra-methylsilane [TMS; Si(CH₃)₄] gases are injected into the working chamber 4 via the vents 42 and 43, wherein the adherent film 322 is deposited tightly on the dissipating base 311 and the dissipating fins 321 due to the bias electric field E and after the ionization process.

For plating the adherent film 312, 322, the flow rate of the hydrogen is maintained at 50-200 sccm while the TMS gas at 50-250 sccm for 1-15 min respectively. The adherent film 312, 322 thus formed consists of Silicon, carborundum (SiC) and a minor portion of hydrocarbon compound. The adherent film 312, 322 has a silicon ratio greater than the noncrystalline DLC material, and therefore adheres securely on the dissipating base 311 and the dissipating fins 321. At this time, the power of the applied electric current supplied by the power supply 61 is maintained at 800-1500 W while the bias electric field E at 400-700V and the working chamber is maintained under between 2-4 μbar.

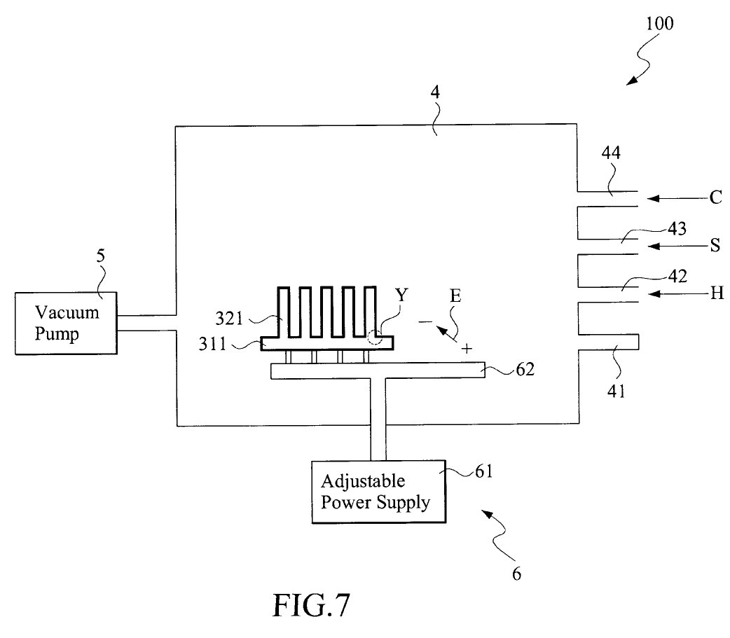

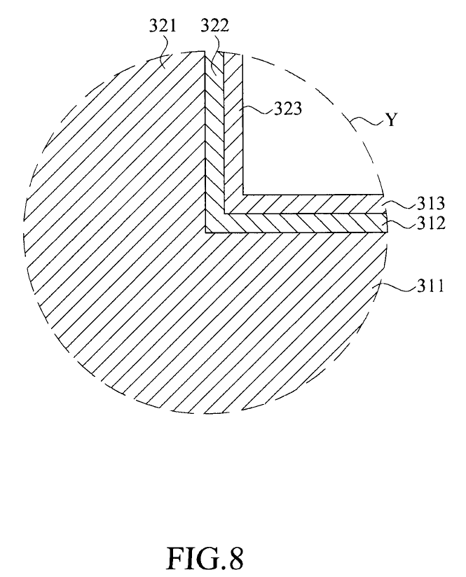

FIG. 7 illustrates how a mixed film being plated on the adherent film according to the method of the present invention. FIG. 8 is an enlarged view of the encircled portion (Y) shown in FIG. 7. In order to form a mixed film 313, 323 over the adherent film 312, 322, the vent 41 is closed firstly, and afterwards, hydrocarbon gas together with the hydrogen and tetra-methylsilane gases are injected into the working chamber via the vents 42, 43 and 44, thereby depositing the mixed film 313, 323 over the adherent film 312, 322 due to the ionization process caused by the bias electric field E. The hydrocarbon gas in this embodiment is Acetylene gas C.

It takes 1-35 min for depositing the mixed film 313, 323 over the adherent film 312, 322. During this period, the flow rate of Acetylene gas C is maintained at 50-800 sccm, the flow rate of drogen is maintained at 50-800 sccm while the flow rate of the TMS gas S is maintained at 50-250 sccm. The applied electric current supplied by the power supply 61 is maintained at 800-1500 W so as to generate the bias electric field with 400-700V. The working chamber is maintained between 4-15 μbar. The mixed film 313, 323 thus formed consists of carborundum (SiC), noncrystalline DLC (diamond-like carbon) material and a minor portion of silicon. Since the mixed film 313, 323 has composition (such as Si and SiC) of the adherent film 312, 322, the material of the mixed film 313, 323 at the initial plating stage is similar to that of the adherent film 312, 322 so that the mixed film 313, 323 can be securely adhered on the adherent film 312, 322.

During deposition of the mixed film 313, 323, by slightly increasing the flow rate of Acetylene gas C, hydrogen and tetra-methylsilane gases, the mixed film 313, 323 thus formed accordingly has the following features. The mixed film 313, 323 has a distal portion that is spaced farthermost from the dissipating base 311 and the dissipating fins 321 and that contains larger noncrystalline DLC (diamond-like carbon) material when compared to the remaining portion of the mixed film 323 and a proximate portion that contains composition similar to the adherent film 322.

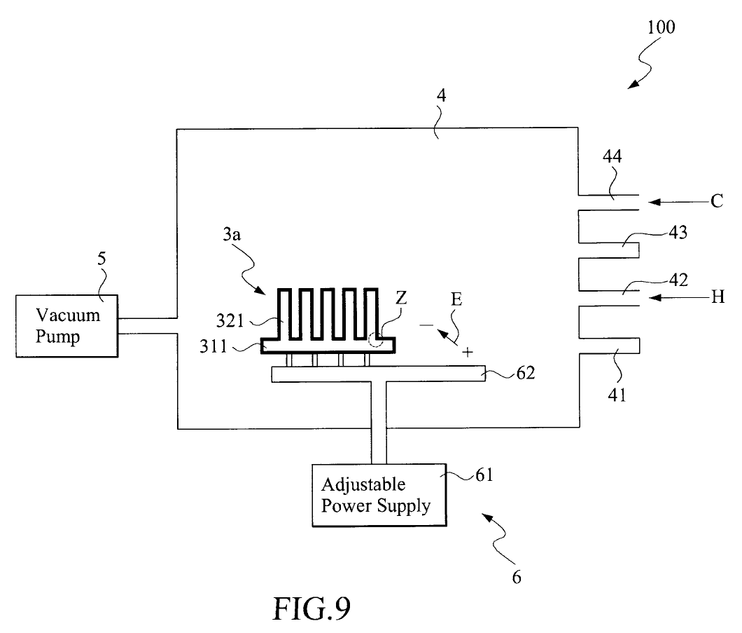

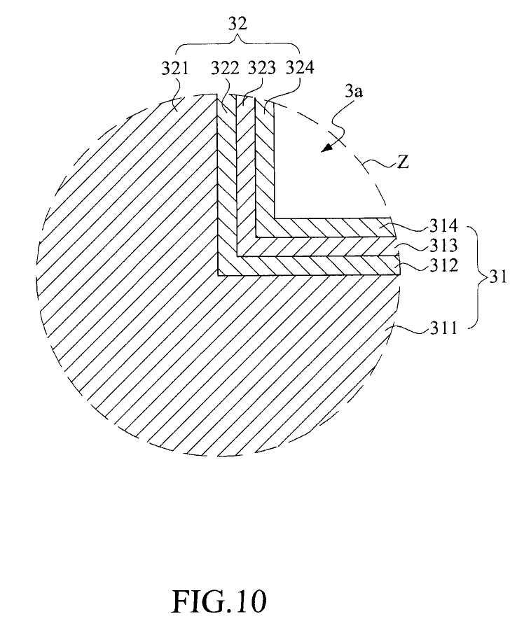

FIG. 9 illustrates how a noncrystalline DLC film 314, 324 being plated over the mixed film 313, 323 according to the method of the present invention. FIG. 10 is a cross sectional view of the heat dissipating module taken along an encircle portion Z in FIG. 9. For plating the noncrystalline DLC film 314, 324, the vent 41 in shut up immediately, the vent 42 is gradually shut up while the vents 42, 44 are open to inject the H and Acetylene gases into the working chamber 4. By ionization process due to the bias electric field E, the noncrystalline DLC film 314, 324 is deposited over the mixed film 313, 323. At this time, the plated dissipating base 31 includes the dissipating base 311 plated with the adherent film 312, the mixed film 313 and the noncrystalline DLC film 314. The plated dissipating fin 32 includes the dissipating fin 321 the adherent film 322, the mixed film 323 and the noncrystalline DLC film 324. In other words, the plated heat dissipation module 3a consists of the plated dissipating base 31 and the plated dissipating fin 32.

It takes 1-200 min for depositing the noncrystalline DLC film 314, 324 over the mixed film 313, 323. During this period, the flow rate of hydrogen and Acetylene is maintained at 50-800 sccm while the flow rate of the TMS gas S is reduced gradually to 0 sccm. The applied electric current supplied by the power supply 61 is maintained at 800-1500 W so as to generate the bias electric field E with 400-700V. The working chamber is maintained between 2-20 μbar.

The outermost part of the mixed film 323 has the composition very similar to the noncrystalline DLC film 324. Thus, the noncrystalline DLC film 324 can tightly adhered on the mixed film 323. At the same time, since the mixed film 323 is tightly adhered on the adherent film 322, which, in turn, is tightly adhered on the main axle 321, the plated driven shaft 32 has the noncrystalline DLC film 324 tightly attached thereon.

From the above mentioned explanation, it is apparent for those skilled in the art and when compare to the prior art plating method, in the film-plating method of the present invention, the adherent film 312, 322, the mixed film 313,323, and the noncrystalline DLC film 314, 324 are deposited successively on the dissipating base 311 and the dissipating fins 321. Thus, the noncrystalline DLC film 314, 324 adheres tightly on the dissipating base 311 and the dissipating fins 321 to form the plated heat dissipation module 3a. Since the noncrystalline DLC film has a balanced ions bonding and enhanced heat dissipating ability, the heat dissipating effect of the plated heat dissipation module is increased.

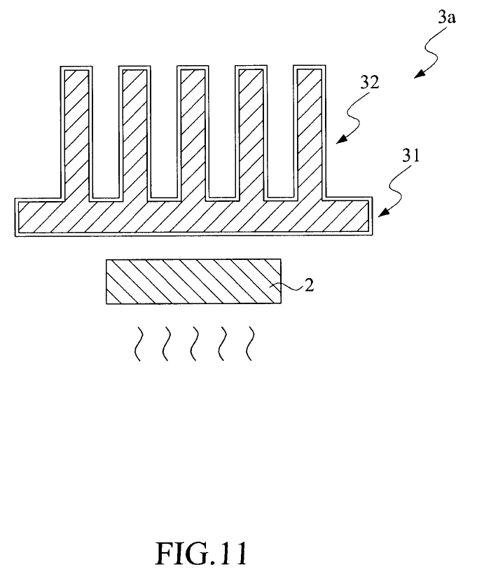

FIG. 11 shows a plated heat dissipation module formed according to the present method dissipating heat generated by a function element. As illustrated, the plated heat dissipation module 3a formed accordingly is used to dissipate the heat generated by the function element 2. An experiment is conducted under the conditions that the present plated heat dissipation module 3a the prior art heat dissipation module 1 having the similar geometric dimension and the same function elements. The experiment testifies for the enhanced heat dissipating ability of the present plated heat dissipation module 3a.

An LED (light emitting diode) serves as the function element 2 in the aforesaid experiment and has a power of 5 W. When the prior and present heat dissipation modules 1, 3a are used respectively to dissipate the heat generated due to operation of the LED for 15 mins, the external surface of function element 2 has 70° C. and 63° C. respectively, thereby testifying for the enhanced heat dissipating ability of the present plated heat dissipation module 3a.

While the invention has been described in connection with what is considered the most practical and preferred embodiments, it is understood that this invention is not limited to the disclosed embodiments but is intended to cover various arrangements included within the spirit and scope of the broadest interpretation so as to encompass all such modifications and equivalent arrangements.

What is claimed is:

1. A method for plating films on an external surface of a heat dissipation module comprising the steps of:
(a) preparing the heat dissipation module;
(b) cleaning the external surface of the heat dissipation module;
(c) disposing the heat dissipation module into a working chamber, injecting hydrogen and tetra-methylsilane [TMS; Si(CH₃)₄] gases therein and applying an electric current to generate a bias electric field within the working chamber, thereby forming an adherent film on the external surface of the heat dissipation module;
(d) injecting hydrocarbon gas together with the hydrogen and tetra-methylisilane gases into the working chamber, thereby plating a mixed film on an external surface of the adherent film, wherein the mixed film consisting of noncrystalline DLC (diamond-like carbon) material and composition of the adherent film, the mixed film having a distal portion that is spaced farthermost from the heat dissipation module and that consists of larger noncrystalline DLC (diamond-like carbon) material when compared to the remaining portion of the mixed film; and
(e) injecting the hydrogen and tetra-methylisilane gases together with hydrocarbon gas into the working chamber, thereby plating a noncrystalline DLC film on the mixed film.

2. The method for plating films according to claim 1, wherein the step (b) further includes the following substeps of:
(b1) disposing the heat dissipation module into the working chamber;
(b2) applying the electric current to generate the bias electric field within the working chamber;
(b3) injecting at least one gas into the working chamber; and
(b4) utilizing the bias electric field to convert the gas into a plasma-like substance so as to clean the external surface of the heat dissipation module.

3. The method for plating films according to claim 2, wherein the step (b) further includes the following substeps of:
cleaning for a first cleaning section of 10-35 min while the working chamber is maintained under pressure of 4-15 μbar, the bias electric field at 300-700V and the power of the applied electric current at 600-1400 W.

4. The method for plating films according claim 3, wherein during the first cleaning section, the gas in the working chamber consists of argon and hydrogen, the argon and hydrogen having a flow rate of 50-200 sccm (standard cc/min) respectively, the gas being converted into plasma-like argon ions and plasma-like hydrogen ions after an ionization process.

5. The method for plating films according to claim 2, wherein the step (b) further includes the following substeps of:
cleaning for a second cleaning section of 10-45 min while the working chamber is maintained under pressure of 2-15 μbar, the bias electric field at 300-700V and the power of the applied electric current at 600-1400 W.

6. The method for plating films according to claim 5, wherein during the second cleaning section, the gas in the working chamber consists of argon and hydrogen, the argon and the hydrogen having a flow rate of 50-420 sccm (standard cc/min) respectively, the gas being converted into plasma-like argon ions and plasma-like hydrogen ions after an ionization process.

7. The method for plating films according to claim 1, wherein an adjustable power source supplier is used for supplying the external electric current.

8. The method for plating films according to claim 1, wherein in the step (c), flow rate of the hydrogen is maintained at 50-200 sccm while the TMS gas at 50-250 sccm for 1-15 min respectively.

9. The method for plating films according to claim 1, wherein during the step (c), the working chamber is maintained under pressure of 2-15 μbar, the bias electric field at 400-700V and the power of the applied electric current at 800-1400 W.

10. The method for plating films according to claim 1, wherein in the step (d), flow rate of the hydrogen is maintained at 50-800 sccm and the TMS gas at 50-250 sccm for 1-10 min respectively, the hydrocarbon gas being acetylene having a flow rate maintained at 50-800 sccm.

11. The method for plating films according to claim 1, wherein during the step (d), the working chamber being maintained under pressure of 4-15 μbar, the bias electric field at 400-700V and the power of the applied electric current at 800-1400 W.

12. The method for plating films according to claim 1, wherein in the step (e), flow rate of the hydrogen is maintained at 50-800 sccm while flow rate of the TMS gas is lowered gradually to 0 sccm within 1-200 min respectively, the hydrocarbon gas being acetylene having a flow rate maintained at 50-800 sccm.

13. The method for plating films according to claim 1, wherein in the step (e), the working chamber is maintained under pressure of 2-20 μbar, the bias electric field at 400-700V and the power of the applied electric current at 800-1400 W.

14. The method for plating films according to claim 1, wherein the adherent film consists of carborundum (SiC), the mixed film consisting of noncrystalline DLC material and silicon carbide.

15. The method for plating films according to claim 1, wherein the heat dissipation module includes a dissipating base and a plurality of fins integrally formed with the dissipating base.

16. The method for plating films according to claim 15, wherein a plated heat dissipation module formed accordingly includes the dissipating base covered by the adherent film, the mixed film and the noncrystalline DLC film successively, and the plurality of fins integrally formed with the plated dissipating base and covered by the adherent film, the mixed film and the noncrystalline DLC film successively.

17. A plated heat dissipation module comprising:
a heat dissipation module;
an adherent film deposited on an external surface of the heat dissipation module;
a mixed film deposited on the adherent film, the mixed film having a noncrystalline DLC material and composition of the adherent film, the mixed film further having a distal portion that is spaced farthermost from the heat dissipation module and that consists of larger noncrystalline DLC (diamond-like carbon) material when compared to the remaining portion of the mixed film; and
a noncrystalline DLC film deposited on the mixed film.

18. The plated heat dissipation module according to claim 17, wherein the heat dissipation module includes a dissipating base and a plurality of fins integrally formed with the dissipating base.

19. The plated heat dissipation module according to claim 18, wherein the plated heat dissipation module formed accordingly includes
the dissipating base covered by the adherent film, the mixed film and the noncrystalline DLC film successively; and
a plurality of fins integrally formed with the dissipating base and covered by the adherent film, the mixed film and the noncrystalline DLC film successively.
